(19) United States
(12) Patent Application Publication
(10) Pub. No.: US 2004/0031970 A1
(43) Pub. Date: Feb. 19, 2004

(54) Process for retarding lateral diffusion of phosphorous

(76) Inventors: Srinivasan Chakravarthi, Richardson, TX (US); PR Chidambaram, Richardson, TX (US)

Correspondence Address: TEXAS INSTRUMENTS INCORPORATED, P O BOX 655474, M/S 3999, DALLAS, TX, 75265

(21) Appl. No.: 10/218,269

(22) Filed: Aug. 13, 2002

(51) Int. Cl. H01L 31/0328

(52) U.S. Cl. 257/197

(57) ABSTRACT

A method of forming a semiconductor device includes doping at least one region of an at least partially formed semiconductor device with at least a phosphorous dopant. The method also includes implanting a diffusion retarding material in the at least partially formed semiconductor device to form at least one diffusion retarding region. The method further includes activating the at least one region of the at least partially formed semiconductor device.

### TECHNICAL FIELD OF THE INVENTION

This invention relates generally to the field of semiconductor devices and, more particularly, to a method for retarding lateral diffusion of phosphorous from the source and drain regions of the semiconductor device.

### BACKGROUND

As semiconductor manufacturers continue to reduce the scale of semiconductor devices, the dopants of the source/drain areas of transistors can laterally diffuse into the channel region during activation, which is undesirable. Conventional methods for minimizing lateral diffusion into the channel region often leads to a reduction in the dopant concentration of the active areas. Reducing the dopant concentration can lead to an increase in semiconductor device sheet resistance, a lower semiconductor device drive current, and a reduced gate drain overlap capacitance.

### SUMMARY OF EXAMPLE EMBODIMENTS

In a method embodiment, a method of forming a semiconductor device comprises doping at least one region of an at least partially formed semiconductor device with at least a phosphorous dopant. The method also comprises implanting a diffusion retarding material in the at least partially formed semiconductor device to form at least one diffusion retarding region. The method further comprises activating the at least one region of the at least partially formed semiconductor device.

In one embodiment, a transistor formed using a method comprising doping at least one region of an at least partially formed semiconductor device with at least a phosphorous dopant. The method also comprises implanting a diffusion retarding material in the at least partially formed semiconductor device to form at least one diffusion retarding region. The method further comprises activating the at least one region of the at least partially formed semiconductor device.

Depending on the specific features implemented, particular embodiments of the present invention may exhibit some, none, or all of the following technical advantages. Various embodiments minimize phosphorous diffusion into the channel region of the semiconductor device. Some embodiments may substantially improve semiconductor device conductivity and improve the gate to drain capacitance of the semiconductor device.

Other technical advantages will be readily apparent to one skilled in the art from the following figures, descriptions and claims. Moreover, while specific advantages have been enumerated above, various embodiments may include all, some or none of the enumerated advantages.

### BRIEF DESCRIPTION OF THE DRAWINGS

For a more complete understanding of embodiments of the present invention, and for further features and advantages thereof, reference is now made to the following description taken in conjunction with the accompanying drawings, in which:

FIGS. 1A through 1G are cross sectional views illustrating one example of a method of forming a portion of a semiconductor device; and

FIG. 2 is a graph comparing the vertical diffusion of phosphorous of a semiconductor device with diffusion retarding regions to a semiconductor device without diffusion retarding regions.

### DETAILED DESCRIPTION OF EXAMPLE EMBODIMENTS

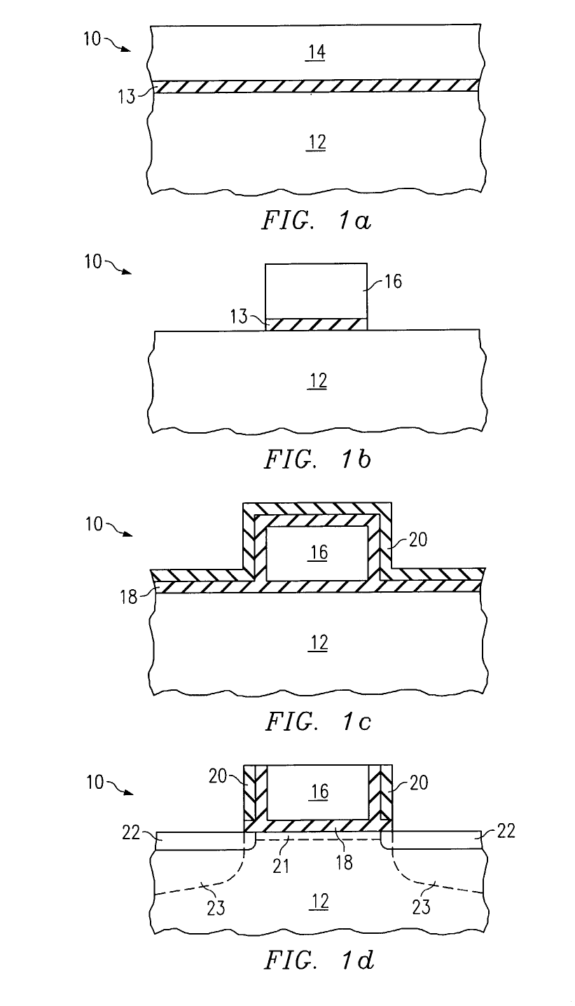

FIGS. 1A through 1G are cross-sectional views showing one example of a method of forming a portion of semiconductor device 10. Semiconductor device 10 may be used as a basis for forming any of a variety of semi-conductor devices, such as a bipolar junction transistor, a NMOS transistor, a PMOS transistor, a CMOS transistor, or other semiconductor based devices. Particular examples and dimensions specified throughout this document are intended for example purposes only, and are not intended to limit the scope of the present disclosure. Moreover, the illustration in FIGS. 1A through 1G are not intended to be to scale.

FIG. 1A shows a cross sectional view of semiconductor device 10 after formation of a gate dielectric layer 13 disposed outwardly from a semiconductor substrate 12 and after formation of a gate electrode layer 14 outwardly from gate dielectric layer 13. Although gate dielectric layer 13 and gate electrode layer 14 are shown as being formed without interstitial layers between them, such interstitial layers could alternatively be formed without departing from the scope of the present disclosure. Semiconductor substrate 12 may comprise any suitable material used in semiconductor chip fabrication, such as silicon or germanium. Gate dielectric layer 13 may comprise, for example, oxide, silicon dioxide, or oxi-nitride.

Forming gate dielectric layer 13 may be effected through any of a variety of processes. In one non-limiting example, gate dielectric layer 13 can be formed by growing an oxide. Using a grown oxide as gate dielectric layer 13 is advantageous in providing a mechanism for removing surface irregularities in semiconductor substrate 12. For example, as oxide is grown on the surface of substrate 12, a portion of substrate 12 is consumed, including at least some of the surface irregularities.

At some point, the active areas of semiconductor device 10 can be formed. Active areas of semiconductor device 10 may be formed, for example, by doping those areas to adjust the threshold voltage Vₜ of semiconductor device 10. This doping may comprise, for example, low energy ion implantation through gate dielectric layer 13. In an alternative embodiment, doping of the active regions of semiconductor device 10 can occur before formation of gate dielectric layer 13. In one particular embodiment (not explicitly shown), a sacrificial dielectric layer may be disposed before formation of gate dielectric layer 13. In that case, the active regions of semiconductor device 10 are doped by implantation through the sacrificial dielectric layer. Then, the sacrificial dielectric layer is removed, and gate dielectric layer 13 is formed.

Gate electrode layer 14 may comprise, for example, amorphous silicon or polysilicon. In this example, gate electrode layer 14 comprises polysilicon. Forming gate electrode layer 14 may be effected, for example, by depositing polysilicon.

In some embodiments, after forming gate electrode layer 14, gate electrode layer 14 may be doped to achieve a relatively high inversion capacitance. The term “inversion capacitance” refers to the capacitance of semiconductor device 10 while the semiconductor device is under inversion. Gate electrode layer 14 may be doped through any of a variety of processes, such as, for example, by ion implantation. In various embodiments, ion implantation of gate dielectric layer 14 may comprise a relatively high-dose of phosphorous and/or arsenic dopants. The use of phosphorous dopants during the ion implantation of gate electrode layer 14 tends to result in higher dopant activation within layer 14, when compared to a similar concentration of other dopants. This higher resultant dopant activation is particularly advantageous in improving the inversion capacitance and the drive current of semiconductor device 10.

FIG. 1B shows a cross sectional view of semiconductor device 10 after formation of a semiconductor gate 16 outwardly from substrate 12. Forming semiconductor gate 16 may be effected through any of a variety of processes. For example, semiconductor gate 16 can be formed by patterning and etching gate electrode layer 14 and gate dielectric layer 13 using photo resist mask and etch techniques.

FIG. 1C shows a cross sectional view of semiconductor device 10 after formation of a first screen dielectric layer 18 outwardly from semiconductor substrate 12 and after formation of a first spacer layer 20 outwardly from first screen dielectric layer 18. Although first screen dielectric layer 18 and first spacer layer 20 are shown as being formed without interstitial layers between them, such interstitial could alternatively be formed without departing from the scope of the present disclosure. First screen dielectric layer 18 may comprise, for example, oxide, oxi-nitride, or silicon oxide.

Forming first screen dielectric layer 18 may be effected through any of a variety of processes. For example, first screen dielectric layer 18 can be formed by growing an oxide. In this particular embodiment, first screen dielectric layer 18 combines with gate dielectric layer 13 during the formation of layer 18. Using a grown oxide as first screen dielectric layer 18 is advantageous in providing a mechanism for removing surface irregularities in substrate 12 and semiconductor gate 16 created during the formation of gate 16.

First spacer layer 20 may comprise any dielectric material, such as, for example, nitride, silicon nitride, oxide, oxi-nitride, or silicon oxide. Forming first spacer layer 20 may be effected through any of a variety of processes. In one non-limiting example, first spacer layer 20 can be formed by depositing a nitride.

In the illustrated embodiment, first screen dielectric layer 18 comprises a dielectric material that is selectively etchable from first spacer layer 20. That is, each of first screen dielectric layer 18 and first spacer layer 20 can be removed using an etchant that does not significantly affect the other. In one non-limiting example, first screen dielectric layer 18 may comprise a layer of oxide while first spacer layer 20 may comprise nitride. In an alternative embodiment, first spacer layer 20 can comprise a dielectric material that is incapable of being selectively etched from first screen dielectric layer 18.

In this particular embodiment, first spacer layer 20 is formed outwardly from first screen dielectric layer 18. In an alternative embodiment, the thickness of first screen dielectric 18 may be increased to a point that substantially negates the need for the formation of first spacer layer 20 outwardly from first screen dielectric layer 18. In this example, the formation of first screen dielectric layer 18 may be effected, for example, by growing an oxide, by depositing an oxide, or a combination of growing and depositing an oxide.

FIG. 1D shows a cross sectional view of semiconductor device 10 after removal of at least a portion of first screen dielectric layer 18 and at least a portion of first spacer layer 20, and after formation of extension areas 22 and diffusion retarding regions 23. Portions of first screen dielectric layer 18 and first spacer layer 20 may be removed, for example, by anisotropically etching first screen dielectric layer 18 and first spacer layer 20. In one non-limiting example, portions of first screen dielectric layer 18 and first spacer layer 20 are removed by performing a plasma etch.

In this embodiment, portions of first screen dielectric layer 18 disposed outwardly from extension areas 22 are completely removed. In an alternative embodiment, portions of first screen dielectric layer 18 remain disposed outwardly from extension areas 22 after removal of portions of layers 18 and 20. Leaving at least a portion of first screen dielectric layer 18 disposed outwardly from extension areas 22 can be advantageous in reducing surface irregularities of substrate 12 formed during the etching process.

In various embodiments, extension areas 22 may comprise a relatively high-doping concentration of phosphorous and/or arsenic dopants. The dopant concentration of extension areas 22 depends at least in part on the desired sheet resistance of semiconductor device 10. Increasing the dopant concentration in extension areas 22 typically results in a lower sheet resistance of semiconductor device 10.

At some point, extension areas 22 of semiconductor device 10 can be formed. In one non-limiting example, extension areas 22 of semiconductor device 10 can be formed by ion implantation. In this particular embodiment, extension areas 22 are formed by implanting phosphorous and arsenic dopants at an implantation dose of approximately 1×10¹⁴ cm⁻² to 4×10¹⁵ cm⁻². Extension areas 22 may be formed, for example, before removal of portions of first screen dielectric layer 18 and first spacer layer 20. In another embodiment, extension areas 22 may be formed after removal of at least a portion of first screen dielectric layer 18 and first spacer layer 20. Removing screen dielectric layer 18 after formation of extension areas 22 is advantageous in minimizing damages to semiconductor substrate 12 during formation of extension areas 22, for example, by substantially preventing implant channeling in substrate 12.

In this example, the doping of semiconductor gate 16 occurs after the formation of gate electrode layer 14 and before formation of semiconductor gate 16. In an alternative embodiment, semiconductor gate 16 can be doped before, substantially simultaneously with, or after the formation of extension areas 22. In that case, the doping of gate 16 can comprise implanting phosphorous and/or arsenic dopants with an implantation dose of approximately 1×10¹⁴ cm⁻² to 4×10¹⁵ cm⁻².

Diffusion retarding regions 23 may comprise any diffusion retarding material, such as, for example, fluorine, chlorine, and/or carbon. In this particular embodiment, diffusion retarding regions 23 comprise fluorine formed from a source comprising boron and fluorine (BF₃). Diffusion retarding regions 23 of semiconductor device 10 may be formed, for example, by ion implantation. In various embodiments, ion implantation of diffusion retarding regions 23 comprises implanting the fluorine dopants at a dose of approximately 2×10¹⁴ cm⁻² to 4×10¹⁵ cm⁻² and an implantation energy of approximately 2 to 30 keV. The dose and implantation energy utilized to form diffusion retarding regions 23 depends at least in part on a desired junction depth and a channel length of semiconductor device 10.

At some point, diffusion retarding regions 23 of semiconductor device 10 can be formed. Diffusion retarding regions 23 may be formed, for example, before or after the formation of extension areas 22. In this particular embodiment, diffusion retarding regions 23 are formed substantially simultaneously with the formation of extension areas 22.

FIG. 1E shows a cross sectional view of semiconductor device 10 after formation of a second screen dielectric layer 24 outwardly from substrate 12, a second spacer layer 26 outwardly from second screen dielectric layer 24, and a third screen dielectric layer 28 outwardly from second spacer layer 26. Second screen dielectric layer 24 may comprise, for example, oxide, oxi-nitride, silicon oxide, or nitride. Forming second screen dielectric layer 24 may be effected, for example, by depositing an oxide outwardly from substrate 12.

Second spacer layer 26 may comprise any dielectric material such as, for example, nitride, silicon nitride, oxide, oxi-nitride, or silicon oxide. In this particular example, second spacer layer 26 comprises nitride. Using nitride as the dielectric material of second spacer layer 26 is particularly advantageous in controlling the etching process. Formation of second spacer layer 26 may be effected, for example, by depositing a dielectric material outwardly from second screen dielectric layer 24.

In this particular embodiment, second spacer layer 26 is formed outwardly from second screen dielectric layer 24. In an alternative embodiment, the thickness of second screen dielectric layer 24 may be increased to a point that substantially negates the need for the formation of second spacer layer 26 outwardly from second screen dielectric layer 24. Formation of second screen dielectric layer 24 may be effected, for example, by depositing an oxide outwardly from substrate 12.

Third screen dielectric layer 28 may comprise, for example, oxide, oxi-nitride, silicon oxide, or nitride. Forming third screen dielectric layer 28 may be effected through any of a variety of processes. For example, third screen dielectric layer 28 can be formed by depositing a dielectric material outwardly from second spacer layer 26.

In this example, diffusion retarding regions 23 are formed substantially simultaneously with the formation of extension areas 22. In alternative embodiments, diffusion retarding regions 23 can be formed after the formation of second screen dielectric layer 24, after the formation of second spacer layer 26, or after the formation of third screen dielectric layer 28. Forming diffusion retarding regions 23 after the formation of layers 24, 26, or 28 will tend to increase the relative distance between each of diffusion retarding regions 23 and a channel region 21.

FIG. 1F shows a cross sectional view of semi-conductor device 10 after formation of source/drains 30 within substrate 12, and after removal of portions of second screen dielectric layer 24, second spacer layer 26, and third screen dielectric layer 28. Portions of second screen dielectric layer 24, second spacer layer 26, and third screen dielectric layer 28 may be removed, for example, by anisotropically etching layers 24, 26 and 28. In one particular embodiment, portions of layers 24, 26, and 28 may be removed by performing a plasma etch technique.

In various embodiments, source/drains 30 may comprise a relatively high-doping concentration of phosphorous and/or arsenic dopants. In this particular embodiment, source/drains 30 comprise phosphorous and arsenic dopants. Source/drains 30 of semiconductor device 10 may be formed, for example, by high-energy ion implantation. In various embodiments, ion implantation of source/drains 30 comprises implanting each of the phosphorous and/or arsenic dopants at a dose of approximately 1×10¹⁴ cm⁻² to 4×10¹⁵ cm⁻² and an implantation energy of approximately 5 to 50 keV. The implantation energy of the dopants of source/drains 30 depends at least in part on the desired junction depth of source/drains 30. In other words, the higher the implantation energy of the dopants the deeper the junction depth of source/drains 30.

At some point, source/drains 30 of semiconductor device 10 may be formed. Source/drains 30 may be formed, for example, before removal of portions of third screen dielectric layer 28, second spacer layer 26, and/or second screen dielectric layer 24. In this particular embodiment, spacer layer 26 operates to protect extension area 22 disposed inwardly from spacer layer 18 during the formation of source/drains 30. In an alternative embodiment, a portion or portions of some or all of third screen dielectric layer 28, second spacer layer 26, and/or second screen dielectric layer 24 may be removed before formation of source/drains 30. The total thickness of layers 24, 26, and 28 remaining after removal of a portion or portions of the respective layers depends at least in part on a desired thickness necessary to protect substrate 12 and extensions 22 during formation of source/drains 30. In one embodiment, after ion implantation a portion or portions of some or all of layers 24, 26, and 28 are removed by an anisotropic etch. Removing portions of layers 24, 26, and/or 28 after formation of source/drains 30 is advantageous in minimizing damages to semiconductor substrate 12 during formation of source/drains 30, for example, by substantially preventing implant channeling in substrate 12.

In this particular embodiment, diffusion retarding regions 23 are formed substantially simultaneously with extension areas 22. In an alternative embodiment, diffusion retarding regions 23 can be formed before, substantially simultaneously with, or after the formation of source/drains 30.

The location of diffusion retarding regions 23 within substrate 12 depends at least in part on when diffusion retarding regions 23 are formed within semiconductor device 10. In this example, diffusion retarding regions 23 are located within substrate 12 laterally ahead of source/drains 30. In other words, diffusion retarding regions 23 reside in a closer proximity to channel region 21, when compared to source/drains 30. Locating diffusion retarding regions 23 laterally ahead of source/drains 30 before activating the phosphorous dopants of source/drains 30 is advantageous in reducing the lateral diffusion of the phosphorous dopants during the activation process. In other embodiments, source/drains 30 can be located within substrate 12 laterally ahead of diffusion retarding regions 23. In some embodiments, source/drains 30 and diffusion retarding regions 23 can reside in a substantially similar proximity to channel region 21.

FIG. 1G shows a cross sectional view of semi-conductor device 10 after activation of the dopants of extension areas 22 and source/drains 30. The dopants of extension areas 22 and source/drains 30 can be activated by any of a number of processes, such as, for example, by annealing semiconductor device 10. In this particular embodiment, the activation of the dopants in source/drains 30 comprises annealing semiconductor device 10 at a temperature of approximately 1000 to 1100 degrees Celsius. In an alternative embodiment, the activation of the dopants in extension areas 22 comprises annealing semiconductor device 10 at a temperature of approximately 950 degrees Celsius.

One aspect of this disclosure recognizes that implanting a diffusion retarding material in the substrate of a semiconductor device can substantially retard the diffusion of phosphorous dopants in the device during activation. Implanting a diffusion retarding material in the substrate of semiconductor device 10 can alleviate some of the problems conventionally associated with phosphorous dopant diffusion into channel region 21 during activation.

As semiconductor manufacturers continue to reduce the scale of semiconductor devices, the dopants of source/drains 30 and/or extension areas 22 can laterally diffuse into channel region 21 during activation. In some cases, this lateral diffusion can completely encompass channel region 21 of semiconductor device 10. Conventional methods for minimizing lateral diffusion into the channel region often lead to a reduction in the dopant concentration of the source/drains and/or drain extension areas. Reducing the dopant concentration of the source/drains and/or drain extension areas typically results in an increase in semiconductor device sheet resistance, a lower semiconductor device drive current, and a reduced inversion capacitance.

Unlike the conventional methods, semiconductor device 10 implements diffusion retarding regions 23 capable of controlling the diffusion of the phosphorous dopants in source/drains 30 and/or extension areas 22. Controlling the diffusion of the phosphorous dopants enables device manufacturers to optimize channel region 21 by minimizing phosphorous dopant encroachment into region 21. In this particular embodiment, diffusion retarding regions 23 implant fluorine dopants to retard/control the diffusion of phosphorous from source/drains 30 and/or extensions areas 22. Controlling diffusion with fluorine dopants advantageously allows device manufacturers to optimize the implantation energy and dopant concentration of the phosphorous dopants in gate 16, source/drains 30, and/or extension areas 22. Optimizing the implantation energy and dopant concentration of the phosphorous enables device manufacturers to obtain a lower/desired sheet resistance, a desired drive current, and a relatively high inversion capacitance. Similar improvements can be realized by implanting chlorine dopants in diffusion retarding regions 23.

In this example, diffusion retarding regions 23 operate to control/retard the lateral diffusion of the phosphorous dopants of extension areas 22 and/or source/drains 30 into channel region 21 during activation. Controlling the lateral diffusion of the phosphorous dopants within substrate 12 enables device manufacturers to control/optimize channel region 21. Device manufacturers can control the lateral diffusion of the phosphorous dopants by varying the horizontal location and/or dopant concentration of regions 23 within substrate 12. The horizontal location of regions 23 refers to the proximity of regions 23 to channel region 21. In most cases, the closer diffusion retarding regions 23 are to channel region 21 and/or the higher the dopant concentration of regions 23, before activation of the phosphorous dopants, the greater the reduction in the lateral diffusion of the phosphorous dopants during activation.

In this particular embodiment, diffusion retarding regions 23 operate to reduce lateral diffusion of the phosphorous dopants by ten (10) Angstroms or more, when compared to the same semiconductor device formed without diffusion retarding regions 23. In various embodiments, diffusion retarding regions 23 can operate to reduce the lateral diffusion of the phosphorous dopants by fifty (50) Angstroms or more, by one hundred (100) Angstroms or more, by one hundred fifty (150) Angstroms or more, or by two hundred (200) Angstroms or more.

In this example, diffusion retarding regions 23 also operate to aid in controlling the vertical diffusion of the phosphorous dopants and/or the junction depth of semiconductor device 10. Controlling the vertical diffusion of the phosphorous dopants within substrate 12 enables device manufacturers to control the junction depth and dopant concentration of source/drains 30. Device manufacturers can control the vertical diffusion of the phosphorous dopants by varying the implantation energy and/or dopant concentration of regions 23. In some cases, increasing the implantation energy of regions 23 can result in diffusion retarding regions 23 extending deeper within substrate 12. Extending region 23 deeper within substrate 12 and/or increasing the concentration of the dopants in regions 23 typically reduces the vertical diffusion of the phosphorous. In addition, the implantation energy used to form diffusion retarding regions 23 can enable device manufacturers to achieve a desired lateral to vertical diffusion ratio.

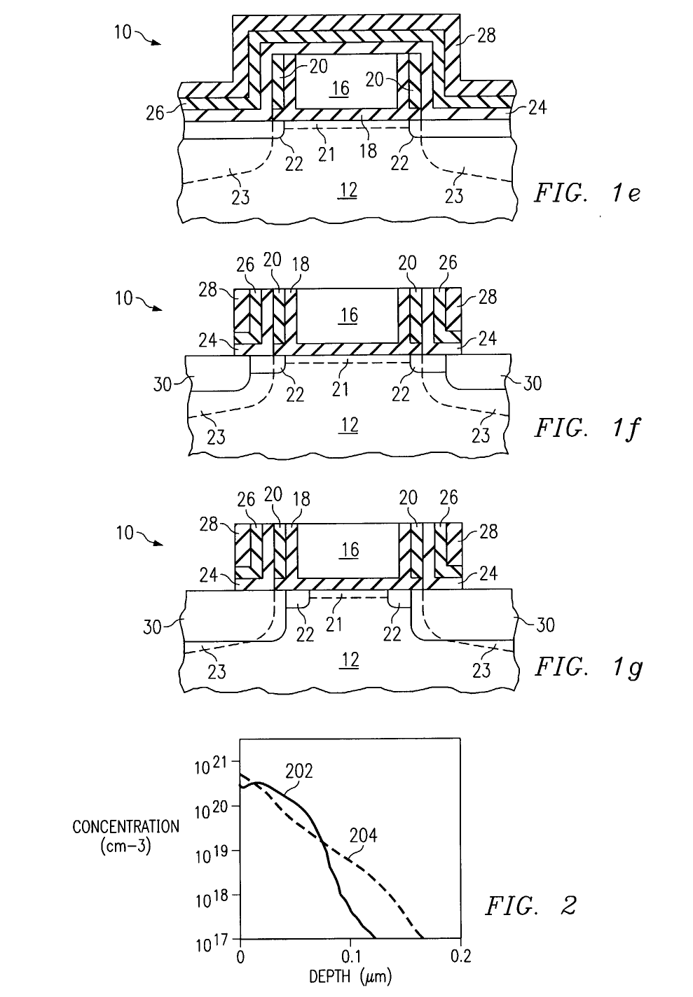

FIG. 2 is a graph comparing the vertical diffusion of phosphorous dopants of a semiconductor device with a fluorine-based diffusion retarding region to a semiconductor device without a diffusion retarding region. In this example, line 202 represents the diffusion of phosphorous in the semiconductor device with a fluorine-based diffusion retarding region. In this particular example, the fluorine-based diffusion retarding region is formed by ion implantation with a fluorine dose of approximately 3×10¹⁵ cm⁻² and an implantation energy of approximately 30 keV. In this example, line 204 represents the diffusion of phosphorous in the semiconductor device without a diffusion retarding region. The horizontal axis represents the vertical diffusion of the phosphorous dopants, while the vertical axis represents the concentration of the phosphorous dopants in the source and/or drain regions of each device.

In this example, each semiconductor device includes a source and drain region implanted with at least phosphorous dopants at an implantation dose of approximately 1.5×10¹⁵ cm⁻² and an implantation energy of approximately 10 keV. This graph illustrates that a fluorine-based diffusion retarding region can be used to retard/control the diffusion of phosphorous dopants in a semiconductor device. Similar results can be realized by implementing a chlorine-based diffusion retarding region.

Although the present invention has been described in several embodiments, a myriad of changes, variations, alterations, transformations, and modifications may be suggested to one skilled in the art, and it is intended that the present invention encompass such changes, variations, alterations, transformations, and modifications as falling within the spirit and scope of the appended claims.

What is claimed is:

1. A method of forming a semiconductor device, comprising:
doping at least one region of an at least partially formed semiconductor device with at least a phosphorous dopant;
implanting a diffusion retarding material in the at least partially formed semiconductor device to form at least one diffusion retarding region; and
activating the at least one region of the at least partially formed semiconductor device.

2. The method of claim 1, wherein the at least one region of the at least partially formed semiconductor device is doped with the at least a phosphorous dopant and at least an arsenic dopant.

3. The method of claim 1, wherein the at least one region of the at least partially formed semiconductor device comprises an extension region.

4. The method of claim 1, wherein the at least one region of the semiconductor device comprises a drain region.

5. The method of claim 1, wherein the at least one region of the semiconductor device comprises a source region.

6. The method of claim 1, wherein the diffusion retarding material comprises a dopant selected from the group consisting of fluorine, chlorine, and carbon.

7. The method of claim 1, wherein the at least one diffusion retarding region is implanted substantially simultaneously with the doping of the at least one region of the at least partially formed semiconductor device.

8. The method of claim 1, wherein the at least one diffusion retarding region is implanted before or after doping the at least one region of the at least partially formed semiconductor device.

9. The method of claim 1, wherein the at least one diffusion retarding region operates to substantially minimize lateral diffusion of the at least a phosphorous dopant of the at least one region into a channel region of the at least partially formed semiconductor device.

10. The method of claim 1, wherein the at least one diffusion retarding region resides in a closer proximity to the channel region of the at least partially formed semiconductor device than the at least one region prior to activating the at least one region.

11. The method of claim 1, wherein the at least one diffusion retarding region reduces a lateral diffusion of the at least one region by ten (10) Angstroms or more when compared to the same at least one region formed in a semiconductor device without the at least one diffusion retarding region.

12. The method of claim 1, wherein the at least one diffusion retarding region reduces lateral diffusion of the at least one region by two hundred (200) Angstroms or more when compared to the same at least one region formed in a semiconductor device without the at least one diffusion retarding region.

13. The method of claim 1, further comprising:
doping at least one extension area of the at least partially formed semiconductor device;
doping at least one drain region of the at least partially formed semiconductor device; and
wherein the at least one drain extension area and the at least one drain region are doped with at least a phosphorous dopant.

14. A method of forming a semiconductor device, comprising:
doping at least one region of an at least partially formed semiconductor device with at least a phosphorous dopant;
implanting a halogen dopant in the at least partially formed semiconductor device to form at least one diffusion retarding region; and
activating the at least one region of the at least partially formed semiconductor device.

15. The method of claim 14, wherein the at least one diffusion retarding region operates to substantially minimize lateral diffusion of the at least a phosphorous dopant of the at least one region into a channel region of the at least partially formed semiconductor device.

16. The method of claim 14, wherein the at least one diffusion retarding region reduces lateral diffusion of the at least one region by ten (10) Angstroms or more when compared to the same at least one region formed in a semiconductor device without the at least one diffusion retarding region.

17. A transistor formed using a method, comprising:
doping at least one region of an at least partially formed semiconductor device, wherein the at least one region is doped with at least a phosphorous dopant;
implanting a diffusion retarding in the at least partially formed semiconductor device to form at least one diffusion retarding region; and
activating the at least one region of the at least partially formed semiconductor device.

18. The transistor of claim 17, wherein the at least one diffusion retarding region operates to substantially minimize lateral diffusion of the at least a phosphorous dopant of the at least one region into a channel region of the at least partially formed semiconductor device.

19. The transistor of claim 17, wherein the at least one diffusion retarding region reduces a lateral diffusion of the at least one region by ten (10) Angstroms or more when compared to the same at least one region formed in a semiconductor device without the at least one diffusion retarding region.

20. The transistor of claim 17, wherein the diffusion retarding material comprises a dopant selected from the group consisting of fluorine, chlorine, and carbon.
